(19) United States
(12) Patent Application Publication
(10) Pub. No.: US 2008/0237681 A1
(43) Pub. Date: Oct. 2, 2008

(54) SEMICONDUCTOR DEVICE AND MANUFACTURING METHOD THEREOF

(75) Inventor: Yoshihiro Minami, Yokosuka-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/051,053

(22) Filed: Mar. 19, 2008

(30) Foreign Application Priority Data
Mar. 30, 2007 (JP) 2007-090901

(51) Int. Cl. H01L 29/788; H01L 21/336

(52) U.S. Cl. 257/315; 438/259; 257/E29.3

(57) ABSTRACT

This disclosure concerns a semiconductor device comprising: a bulk substrate; an insulation layer provided on the bulk substrate; a semiconductor layer containing an active area on which a semiconductor element is formed, and a dummy active area isolated from the active area and not formed with a semiconductor element thereon, the semiconductor layer being provided on the insulation layer; and a supporting unit provided beneath the dummy active area to reach the bulk substrate piercing through the insulation layer, the supporting unit supporting the dummy active area.

### CROSS-REFERENCE TO RELATED APPLICATIONS

This application is based upon and claims the benefit of priority from the prior Japanese Patent Applications No. 2007-90901, filed on Mar. 30, 2007, the entire contents of which are incorporated herein by reference.

### FIELD OF THE INVENTION

The present invention relates to a semiconductor device and a manufacturing method thereof, and relates, for example, a semiconductor device and a manufacturing method thereof having a semiconductor element on an SOI (Silicon On Insulator) structure, for example.

### RELATED ART

In recent years, there has been an FBC device as a semiconductor memory device expected as a memory replacing a 1T (Transistor)-1C (Capacitor)-type DRAM. The FBC memory device forms an FET (Field Effect Transistor) having a floating body (hereinafter, also called a body) on an SOI structure, and stores data “1” or data “0” depending on the number of majority carriers accumulated in this body.

Conventionally, an FBC memory is formed using an SOI substrate. However, because the SOI substrate is expensive, there has been developed a method of forming an SOI structure on a bulk substrate, and forming an FBC on this SOI structure. In this case, a silicon germanium layer becoming a seed of a silicon monocrystal is formed on a bulk substrate, and a silicon monocrystalline layer is epitaxially grown on this silicon germanium layer. Next, the silicon monocrystalline layer in an element isolation region is removed, thereby partially exposing the silicon germanium layer. A total silicon germanium layer is removed from this element isolation region. A silicon oxide film is filled between the silicon monocrystalline layer and the bulk substrate, thereby forming the SOI structure.

However, the etching amount of the silicon germanium layer needs to be limited to a necessary minimum amount. This is because while the silicon germanium layer can be selectively etched to the silicon monocrystal, when the etching time is long, the silicon monocrystalline layer is also unnecessarily etched.

To suppress a dishing in a CMP (Chemical Mechanical Polishing) process at the time of forming an STI, a dummy active area is often laid out within a wide element isolation region. While the dummy active area has an SOI structure which is the same as that of the normal active area, a semiconductor element is not generated in the dummy active area. Because the etching amount of the silicon germanium layer needs to be limited to the necessary minimum amount as described above, when the dummy active area is large, the silicon germanium layer remains beneath the dummy active area. This leads to a self contamination by the silicon germanium. There is also a problem that the dummy active area is removed from the bulk substrate due to the explosive oxidization of the remaining silicon germanium.

When the dummy active area is small, the silicon germanium layer is completely etched, and the dummy active area of the silicon monocrystalline layer is removed from the bulk substrate.

### SUMMARY OF THE INVENTION

A semiconductor device according to an embodiment of the present invention comprises a bulk substrate; an insulation layer provided on the bulk substrate; a semiconductor layer containing an active area on which a semiconductor element is formed, and a dummy active area isolated from the active area and not formed with a semiconductor element thereon, the semiconductor layer being provided on the insulation layer; and a supporting unit provided beneath the dummy active area to reach the bulk substrate piercing through the insulation layer, the supporting unit supporting the dummy active area.

A method of manufacturing a semiconductor device according to an embodiment of the present invention comprises forming a silicon germanium layer on a bulk substrate; forming a first silicon monocrystalline layer on the silicon germanium layer; removing a part of the first silicon monocrystalline layer and a part of the silicon germanium layer within a dummy active area isolated by an element isolation region from an active area in which a semiconductor element is to be formed; forming a silicon pillar within a trench formed by removing the part of the first silicon monocrystalline layer and the part of the silicon germanium layer, and forming a second silicon monocrystalline layer on the first silicon monocrystalline layer; removing the first and the second silicon monocrystalline layers and the silicon germanium layer in the element isolation region; selectively removing the silicon germanium layer in the dummy active area, while leaving the first and the second silicon monocrystalline layers and the silicon pillar in the dummy active area; and embedding an insulation layer beneath the first and the second silicon monocrystalline layers in the dummy active area.

A method of manufacturing a semiconductor device according to an embodiment of the present invention comprises forming a mask layer on a bulk substrate; removing a part of the mask layer within a dummy active area isolated by an element isolation region from an active area in which a semiconductor element is to be formed; forming a porous silicon layer by selectively making porous the surface of the bulk substrate not covered by the mask layer, and forming a silicon pillar beneath the mask layer; removing the mask layer; forming a silicon monocrystal on the porous silicon layer and the silicon pillar; removing the silicon monocrystalline layer and the porous silicon layer in the element isolation region; selectively removing the porous silicon layer in the dummy active area, while leaving the silicon monocrystalline layer and the silicon pillar in the dummy active area; and embedding an insulation layer beneath the silicon monocrystalline layer in the dummy active area.

### BRIEF DESCRIPTION OF THE DRAWINGS

FIG. 1A and FIG. 1B are a top plan view and a cross-sectional view, respectively of an FBC memory according to a first embodiment of the present invention;

FIG. 2A to FIG. 7B are cross-sectional views and top plan views showing the manufacturing method according to the present embodiment;

FIG. 8 is a top plan view of an FBC memory according to a second embodiment of the present invention;

FIG. 9 is a top plan view corresponding to FIG. 3A;

FIG. 10 is a top plan view corresponding to FIG. 5A;

FIG. 11 is a top plan view of an FBC memory according to a third embodiment of the present invention;

FIG. 12 is a top plan view corresponding to FIG. 3A;

FIG. 13 is a top plan view corresponding to FIG. 5A;

FIG. 14A and FIG. 14B showing a distance from the end of the dummy active areas DAA to the end of the supporting units 40; and

FIG. 15A to FIG. 19B are top plan views and cross-sectional views showing a method of manufacturing the FBC memory according to a fourth embodiment of the present invention.

### DETAILED DESCRIPTION OF THE INVENTION

Embodiments of the present invention will be explained below in detail with reference to the accompanying drawings. Note that the invention is not limited thereto.

### First Embodiment

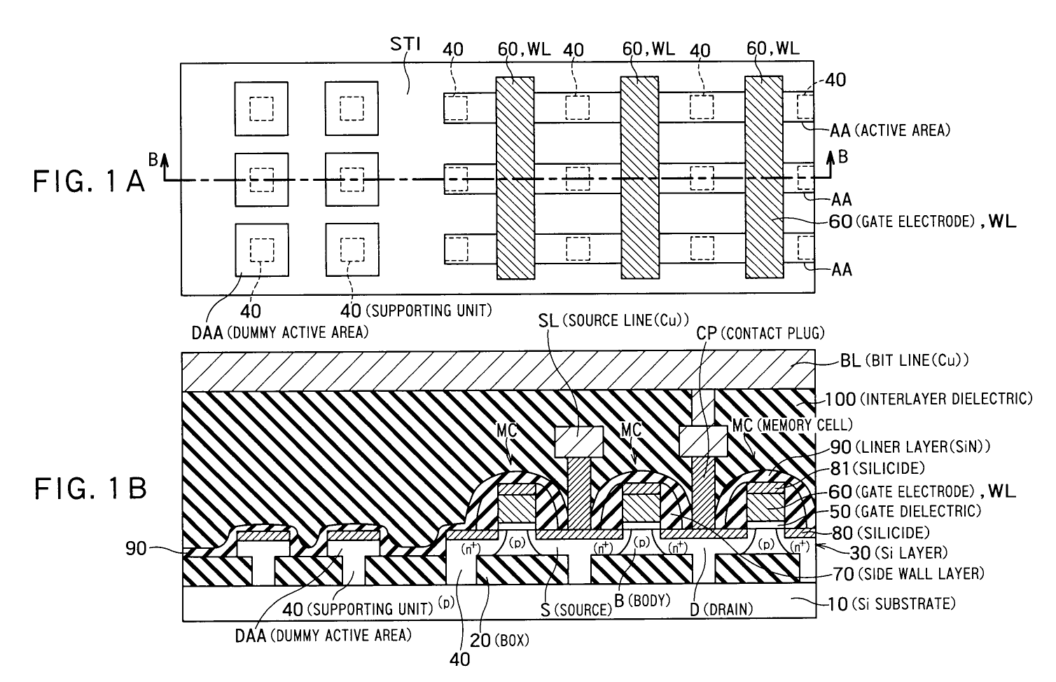

FIG. 1A and FIG. 1B are a top plan view and a cross-sectional view, respectively of an FBC memory according to a first embodiment of the present invention. FIG. 1B is the cross-sectional view of FIG. 1A along a line B-B. This FBC memory includes a bulk silicon substrate 10 (hereinafter, a bulk substrate 10), an embedded insulation film 20 (hereinafter, a BOX (Buried Oxide) layer 20), a silicon monocrystalline layer 30 (hereinafter, a silicon layer 30), supporting units 40, a source layer S, a drain layer D, a gate dielectric film 50, a gate electrode 60, a sidewall layer 70, silicide layers 80, 81, a liner layer 90, an interlayer dielectric film 100, a contact plug CP, a source line SL, and a bit line BL.

The BOX layer 20 is provided on the bulk substrate 10. The silicon layer 30 includes normal active areas AA in which a semiconductor element is formed, and dummy active areas DAA in which a semiconductor element is not formed. The dummy active areas DAA are isolated from the active areas AA, and are laid out within element isolation STI (Shallow Trench Isolation). The dummy active areas DAA are provided to suppress a dishing (gouged) of wide element isolation regions by a CMP at the time of forming the element isolation STI. The supporting units 40 include silicon monocrystal, for example, and are provided to reach the bulk substrate 10 piercing through the BOX layer 20 beneath the dummy active areas DAA. Accordingly, the supporting units 40 fix the dummy active areas DAA to the bulk substrate 10, and support this.

An n-type source layer S and an n-type drain layer D are formed within the silicon layer 30. A p-type body B is provided between the source layer S and the drain layer D. The body B is in an electrically floating state, and accumulates or discharges holes to store data. The gate dielectric film 50 is provided on the body B. The gate dielectric film 50 includes, for example, a silicon oxide film, a silicon nitride film, a silicon oxynitrided film, or a high-dielectric film (for example, HfSiO). The gate electrode 60 includes polysilicon, and is provided on the gate dielectric film 50. The gate electrode 60 also functions as a word line WL. The sidewall layer 70 includes a silicon oxide film or a silicon nitride film, and is provided on the side surface of the gate electrode 60. The sidewall layer 70 is provided to form the source layer S, the drain layer D, and the silicide layer 80 by using self-alignment technique.

The silicide layer 80 is provided on the source layer S and the drain layer D to decrease contact resistance. The silicide layer 81 is provided on the gate electrode 60 to decrease gate resistance. The silicide layers 80 and 81 are nickel silicide, for example. The silicide layer 80 can be also provided on the dummy active areas DAA. This is because even when the silicide layer 80 is formed on the dummy active areas DAA, the effect (dishing suppression effect) of the dummy active areas DAA can be obtained. The liner layer 90 includes a silicon nitride film, and is provided to cover the gate electrode 60 and the sidewall layer 70.

The interlayer dielectric film 100 is provided on the memory cell MC and the dummy active areas DAA. The contact plug CP is in contact with the silicide layer 80 through the interlayer dielectric film 100. The contact plug CP electrically connects the source layer S to the source line SL, and electrically connects the drain layer D to the bit line BL. The bit line BL extends to a direction orthogonal with the extension direction of the word line WL. Accordingly, a memory cell MC present at the intersection between the word line WL and the bit line BL can be selected. The source line SL extends to the same direction as that of the word line WL. The bit line BL and the source line SL include copper.

The memory cell MC is present at the intersection between the word line WL and the bit line BL, and can store logical data (“1” or “0”) depending on the number of holes accumulated in the body B. The memory cell MC is configured by an n-type MISFET (Metal-Isolator-Semiconductor Field Effect Transistor), for example. When the memory cell MC is the n-type MISFET, the logical data is “1” when many holes are accumulated in the body B, and the logical is “0” when a small number of holes are accumulated in the body B.

The supporting units 40 are provided beneath the dummy active areas DAA, the source layer S and the drain layer D. As shown in FIG. 1A, in the plane view of looking at the FBC memory from above the surface of the bulk substrate 10, the peripheries of the supporting units 40 are inside the peripheries of the active areas AA and the dummy active areas DAA. Accordingly, a portion (a portion within the DAA, and not the supporting units) encircled by at least the peripheries of the dummy active areas DAA and the peripheries of the supporting units 40 has the same height of the Si layer as that of the active areas AA. Therefore, dishing of the CMP can be suppressed at the time of forming the STI. The supporting units 40 can support the active areas AA while insulating the body B from the bulk substrate 10.

When the supporting units 40 support the dummy active areas DAA and the active areas AA, the dummy active areas DAA and the active areas AA are not peeled off during the manufacturing process.

The supporting units 40 can be a conductor by selectively implanting an impurity into only the dummy active areas DAA. In this case, the potential of the dummy active areas DAA can be set the same as the potential of the bulk substrate 10. When the dummy active areas DAA are in the electrically floating state, the BOX layer 20 or the memory cell MC has a risk of being destroyed due to the accumulation of charge in the dummy active areas DAA during the manufacturing. When the dummy active areas DAA are in the electrically floating state, this has a risk of negative effect that the characteristic of the memory cell MC becomes unstable. However, when the potential of the dummy active areas DAA is fixed to the potential of the bulk substrate 10 like in the present embodiment, the above problem is not present.

In the present embodiment, while the supporting units 40 are provided immediately below both the source layer S and the drain layer D, the supporting units 40 can be also provided immediately below one of the source layer S and the drain layer D. In this case, the supporting units 40 are formed by a semiconductor of conductivity opposite to that of the source layer S and the drain layer D or the bulk substrate 10. With this arrangement, the source and the substrate can be isolated by a pn-junction, and the drain and the substrate can be isolated by a pn-junction. When the source layer S and the drain layer D are n-type semiconductors and also when the bulk substrate 10 is a p-type semiconductor, for example, the supporting units 40 can be formed by n-type semiconductors. Accordingly, a pn-junction is formed between the source and the substrate, and between the drain and the substrate, respectively. As a result, the source can be isolated from the substrate, and the drain can be isolated from the substrate.

Further, the supporting units 40 can be provided immediately below the body B. However, the body B needs to be in the electrically floating state. Therefore, the supporting units 40 need to be formed by a semiconductor of conductivity opposite to that of the body B or the bulk substrate 10. By this configuration, the body can be isolated from the substrate by a pn-junction. When the body B and the bulk substrate 10 are p-type semiconductors, for example, the supporting units 40 can be formed as an n-type semiconductor. Accordingly, a pn-junction is formed between the body B and the bulk substrate 10, and the body B is isolated from the bulk substrate 10.

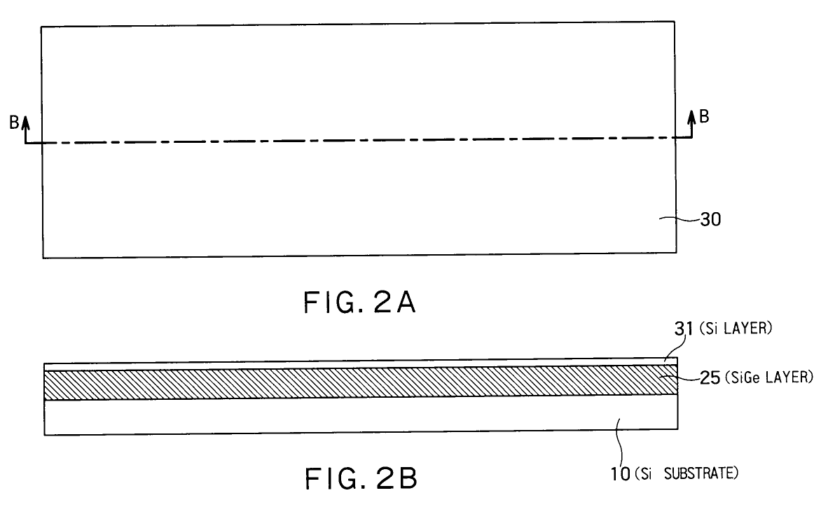

A method of manufacturing the FBC memory according to the present embodiment is explained next. FIG. 2A to FIG. 7B are cross-sectional views and top plan views showing the manufacturing method according to the present embodiment. FIGS. 2A, 3A, 4A, 5A, 6A, and 7A are top plan views, and FIGS. 2B, 3B, 4B, 5B, 6B, and 7B are cross-sectional views. First, the bulk substrate 10 is prepared. As shown in FIG. 2A and FIG. 2B, a silicon germanium layer 25 is epitaxially grown on the surface of the bulk substrate 10. Next, a silicon layer 31 is epitaxially grown on the silicon germanium layer 25 as a first silicon monocrystalline layer. The silicon germanium layer 25 is grown in the monocrystalline state following a crystal orientation of silicon of the bulk substrate 10. The silicon layer 31 grows in the monocrystalline state following the crystal orientation of the silicon germanium layer 25.

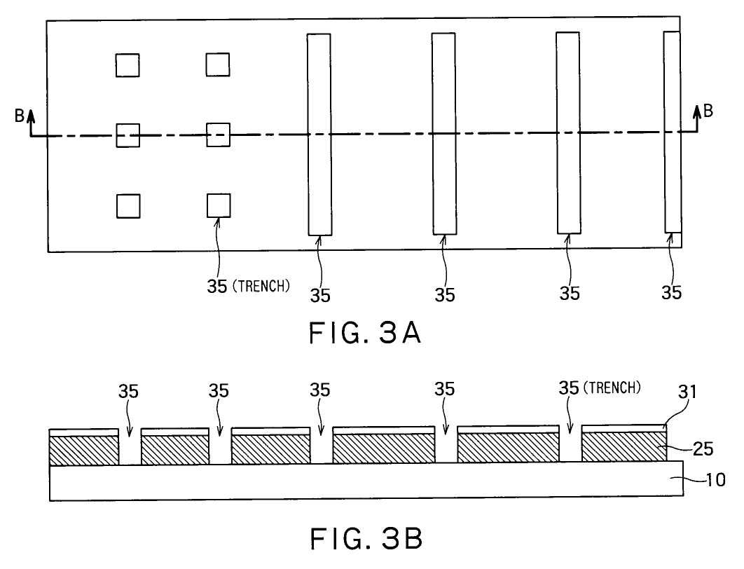

As shown in FIG. 3A and FIG. 3B, the silicon layer 31 and the silicon germanium layer 25 in the formation region of the supporting units 40 are selectively removed by using lithography and RIE (reactive ion etching). Because the formation region of the supporting units 40 is within the range of the active areas AA and the dummy active areas DAA, the silicon layer 31 and the silicon germanium layer 25 removed in this process inevitably become a part of the silicon layer 31 and the silicon germanium layer 25 within the active areas AA and the dummy active areas DAA.

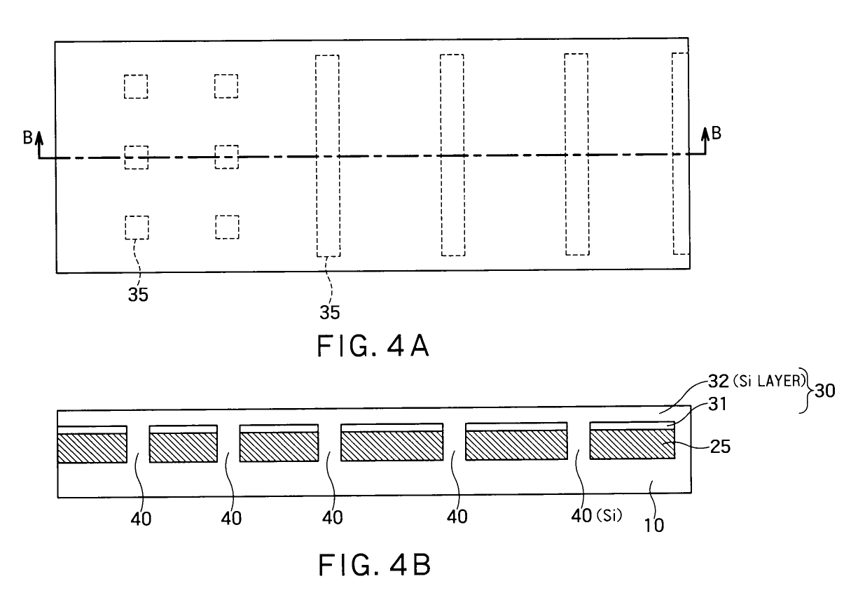

Next, a silicon layer 32 as a second monocrystalline layer is epitaxially grown on the bulk substrate 10 and the silicon layer 31. Accordingly, the silicon layer 32 is implanted into trenches 35, and the supporting units (silicon pillars) 40 are formed within the trenches 35, as shown in FIG. 4A and FIG. 4B. The silicon layer 32 is also formed on the silicon layer 31. The silicon layers 31 and 32 other than the silicon pillars 40 become the silicon layer 30.

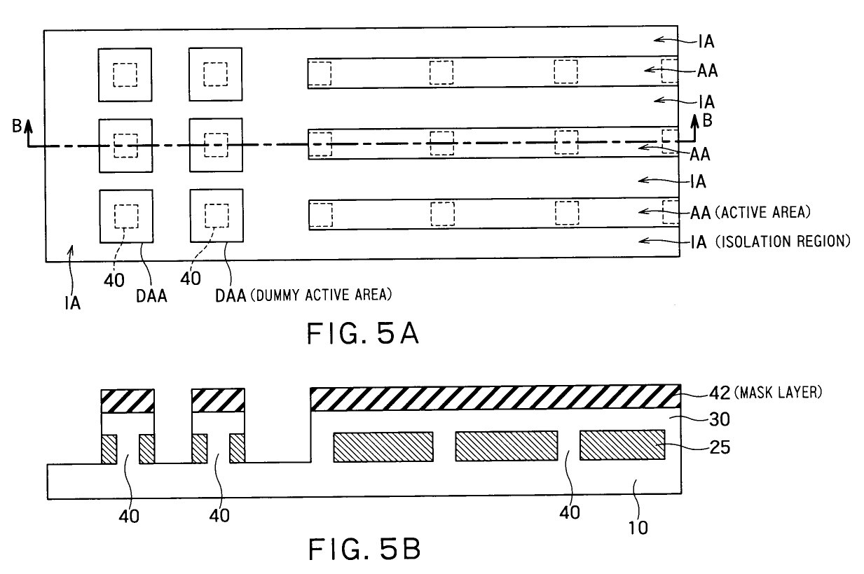

A mask layer 42 covering the active areas AA and the dummy active areas DAA is then formed. The surface of the silicon layer 30 in the element isolation regions IA is exposed. The mask layer 42 includes a silicon nitride film, for example, and is processed by using lithography and RIE. The silicon layer 30 and the silicon germanium layer 25 in the element isolation regions IA are anisotropically etched by using the mask layer 42 as a mask and by using RIE, as shown in FIG. 5A and FIG. 5B.

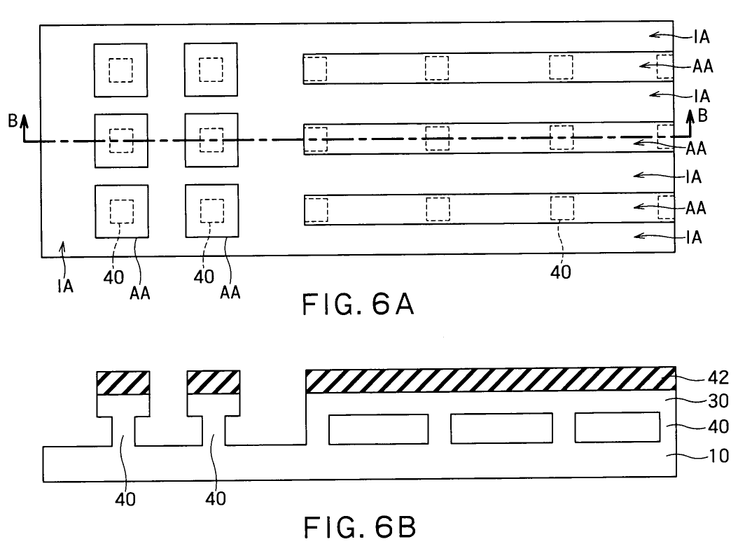

As shown in FIG. 6A and FIG. 6B, the silicon germanium layer 25 beneath the silicon layer 30 is selectively and isotropically etched, while leaving the silicon layer 30 and the silicon pillars 40 in the dummy active areas DAA and the active areas AA as they are.

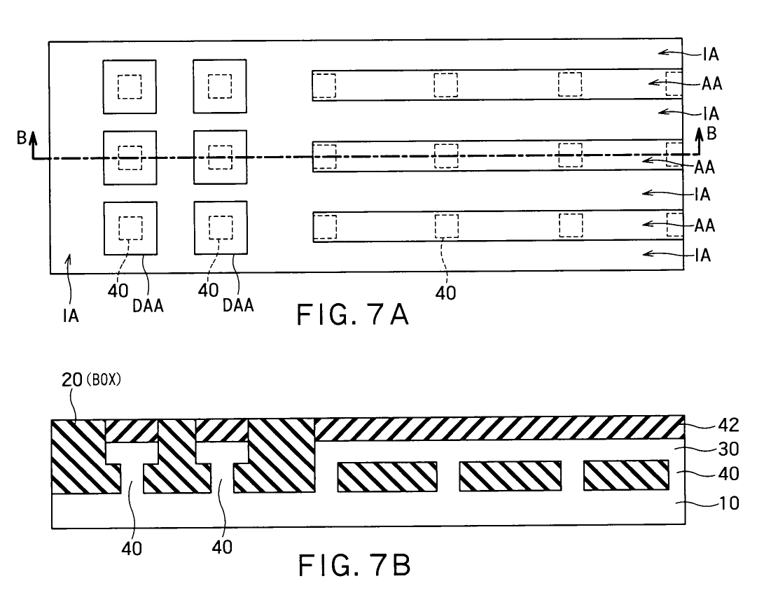

Next, as shown in FIG. 7A and FIG. 7B, the embedded insulation film 20 is embedded into a space formed by removing the silicon germanium layer 25. The embedded insulation film 20 is embedded by thermal oxidization or LPCVD (Low Pressure Chemical Vapor Deposition) or plasma CVD. The embedded insulation film 20 is also formed in the element isolation regions IA. The embedded insulation film 20 is polished to the surface level of the mask layer 42 by using CMP. Accordingly, a structure as shown in FIG. 7B is obtained. In this series of process, the supporting units 40 fix the dummy active areas DAA and the active areas AA to the bulk substrate 10. Therefore, the dummy active areas DAA and the active areas AA are not peeled off during the process.

Thereafter, the height of the embedded insulation film 20 is adjusted by using wet etching. The mask layer 42 is removed. Thereafter, a semiconductor element is formed on the active areas AA by using a known CMOS process, as shown in FIG. 1B.

In the present embodiment, the supporting units 40 are provided within the range of the dummy active areas DAA viewed from above the surface of the bulk substrate 10. A center (barycenter) of each supporting unit 40 substantially coincides with a center (barycenter) of each dummy active area DAA. By forming the supporting units 40 in this way, a distance from the peripheries of the dummy active areas DAA to the peripheries of the supporting units 40, that is, the etching distance of the silicon germanium layer 25, is not deviated to one side and becomes symmetrical with the center (barycenter) of the supporting unit 40. Accordingly, there is no unetched part of the silicon germanium layer 25, and excessive etching of the silicon layer 30 and the supporting unit 40 can be suppressed. As a result, in the present embodiment, peeling off of the dummy active areas DAA and self-contamination due to germanium can be suppressed. The dummy active areas DAA can suppress dishing of the surrounding of the active areas AA by CMP and the like. Suppression of germanium contamination stabilizes the transistor characteristic. A dummy gate (not shown) can be formed on or around the dummy active areas DAA. The dummy gate is provided to avoid the occurrence of dishing in the flattening CMP process of the interlayer dielectric film 100.

### Second Embodiment

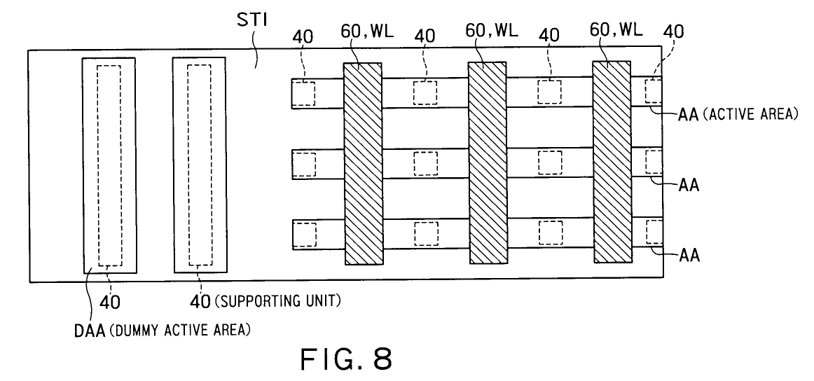

FIG. 8 is a top plan view of an FBC memory according to a second embodiment of the present invention. The second embodiment is different from the first embodiment in that the dummy active areas DAA are formed in a stripe shape. Other configurations of the second embodiment can be similar to those of the first embodiment. A cross-sectional view of the second embodiment is similar to that in FIG. 1B, and therefore, is not shown.

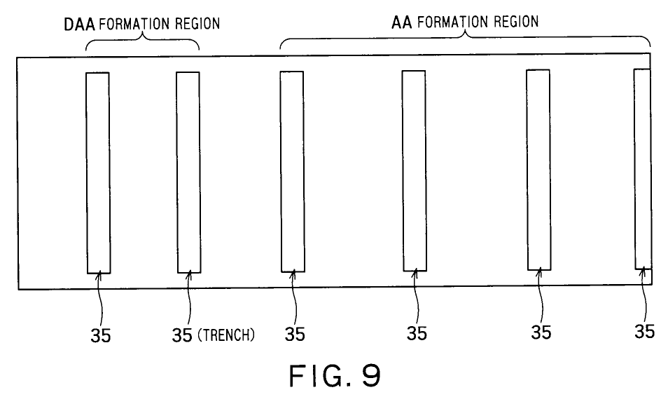

A method of manufacturing the FBC memory according to the second embodiment is similar to that of the first embodiment, and therefore, only a different process is explained. FIG. 9 is a top plan view corresponding to FIG. 3A. In the second embodiment, as shown in FIG. 9, the formation region of the supporting units 40 in the dummy active areas DAA is in a strip shape. This is realized by changing a mask pattern of lithography. The silicon layer 31 and the silicon germanium layer 25 are etched in the pattern shown in FIG. 9, thereby forming the trenches 35.

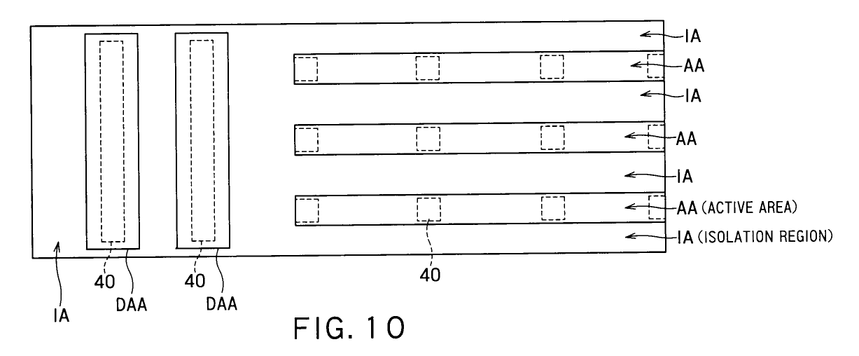

FIG. 10 is a top plan view corresponding to FIG. 5A. In the second embodiment, as shown in FIG. 10, the formation region of the dummy active areas DAA is in a stripe shape. This is realized by changing a mask pattern of lithography. The silicon layer 30 and the silicon germanium layer 25 are etched in the pattern shown in FIG. 10. The second embodiment can achieve effects similar to those in the first embodiment.

### Third Embodiment

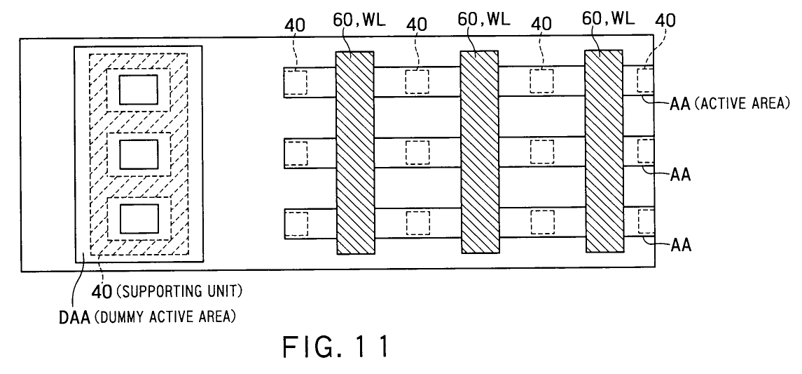

FIG. 11 is a top plan view of an FBC memory according to a third embodiment of the present invention. The third embodiment is different from the first embodiment in that the dummy active areas DAA are formed in a ladder shape (lattice shape). Other configurations of the third embodiment can be similar to those of the first embodiment.

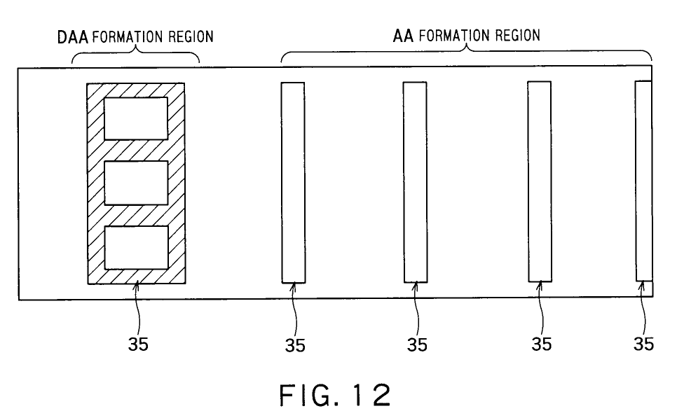

A method of manufacturing the FBC memory according to the third embodiment is similar to that of the first embodiment, and therefore, only a different process is explained. FIG. 12 is a top plan view corresponding to FIG. 3A. In the third embodiment, as shown in FIG. 12, the formation region of the supporting units 40 in the dummy active areas DAA is in a ladder shape (lattice shape). This is realized by changing a mask pattern of lithography. The silicon layer 31 and the silicon germanium layer 25 are etched in the pattern shown in FIG. 12, thereby forming the trenches 35.

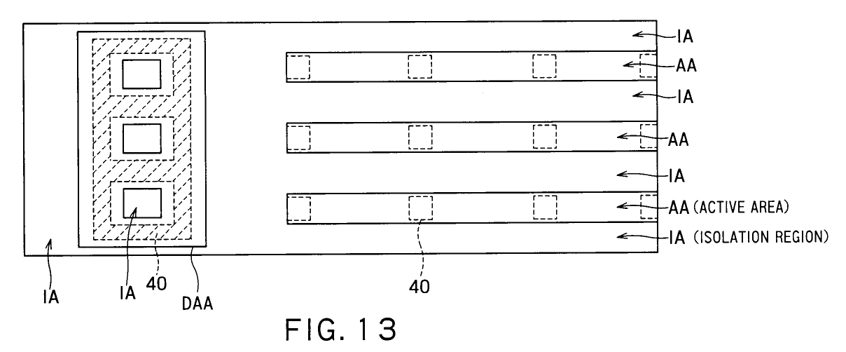

FIG. 13 is a top plan view corresponding to FIG. 5A. In the third embodiment, as shown in FIG. 13, the formation region of the dummy active areas DAA is in a ladder shape (lattice shape). This is realized by changing a mask pattern of lithography. The silicon layer 30 and the silicon germanium layer 25 are etched in the pattern shown in FIG. 13. The element isolation regions IA are also provided within the dummy active areas DAA, as shown in FIG. 13. Therefore, the silicon layer 30 and the silicon germanium layer 25 are also etched in the element isolation regions IA within the dummy active areas DAA. Accordingly, the silicon germanium layer 25 is entirely etched. The third embodiment can further achieve effects similar to those in the first embodiment.

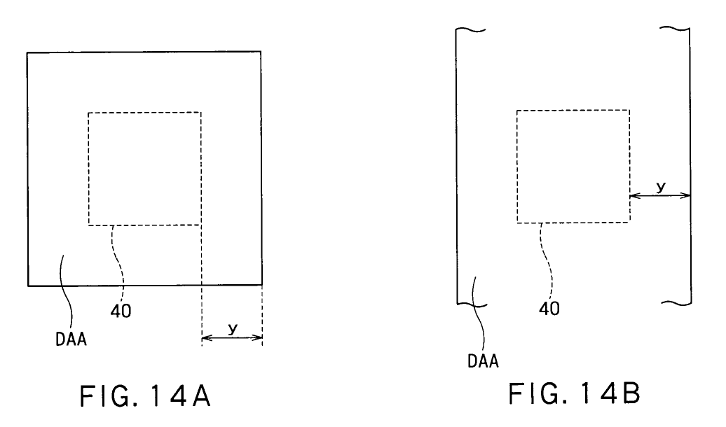

In the first to the third embodiments, a distance from the end of the dummy active areas DAA to the end of the supporting units 40 (y shown in FIG. 14A and FIG. 14B) needs to be about equal to or smaller than a distance x over which the silicon germanium layer 25 needs to be side etched entirely in the active areas AA. Accordingly, the silicon germanium layer 25 is entirely etched. When an etching selection ratio of silicon germanium to silicon is large, both x and y can have large values.

### Fourth Embodiment

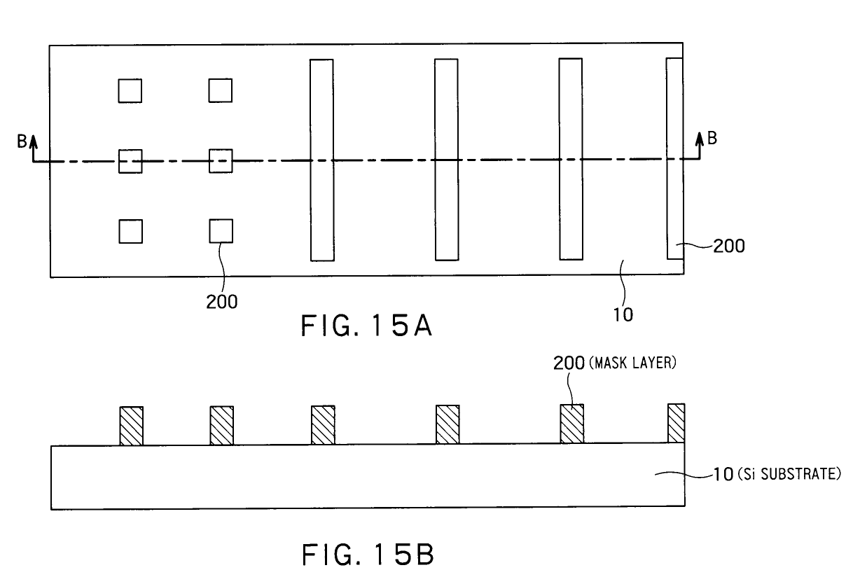

FIG. 15A to FIG. 19B are top plan views and cross-sectional views showing a method of manufacturing the FBC memory according to a fourth embodiment of the present invention. In the manufacturing method according to the fourth embodiment, the structure shown in FIG. 1A and FIG. 1B according to the first embodiment is formed. FIGS. 15A, 16A, 17A, 18A and 19A are top plan views, and FIGS. 15B, 16B, 17B, 18B, and 19B are cross-sectional views. First, the bulk substrate 10 is prepared. As shown in FIG. 15A and FIG. 15B, a mask layer 200 is deposited on the bulk substrate 10. The mask layer 200 is an insulation film such as a silicon oxide film, a silicon nitride film, and a photoresist. The mask layer 200 in the region other than the formation region of the supporting units 40 is selectively removed using a lithography technique and RIE.

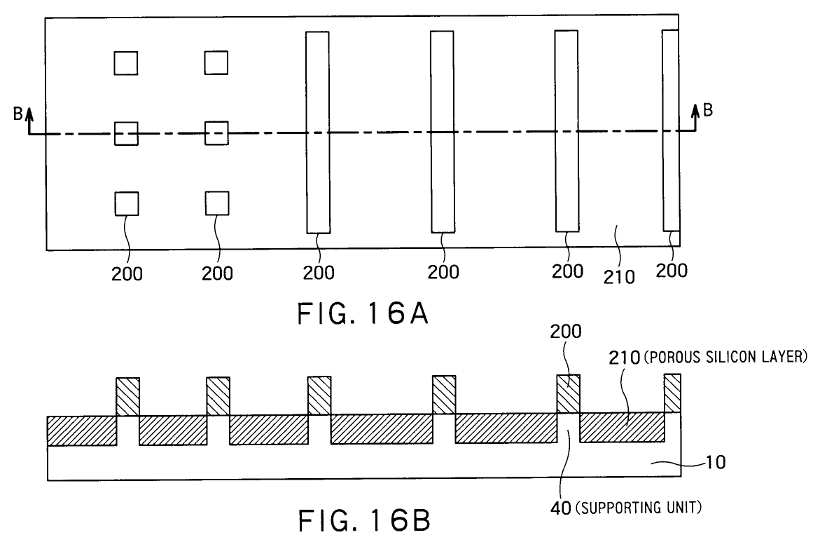

Next, the surface region of the bulk substrate 10 is anodized using the mask layer 200 as a mask. Accordingly, as shown in FIG. 16A and FIG. 16B, the surface region of the bulk substrate 10 other than the supporting units 40 is selectively made porous, thereby forming a porous silicon layer 210. In this case, the bulk substrate 10 (supporting units 40) beneath the mask layer 200 is not made porous. Anodization is a process of passing a current to the supporting substrate 10 in a hydrofluoric acid (HF) and ethanol solution. By performing anodization, fine holes having a diameter of a few nm are formed on the surface region of the bulk substrate 10, and the holes extend to the inside. As a result, many holes extending in a vertical direction to a surface of the bulk substrate 10 are formed on the surface of the bulk substrate 10. Accordingly, the surface region of the bulk substrate 10 is made porous.

An anodized current does not flow through the bulk substrate 10 covered with the mask layer 200. Therefore, silicon pillars becoming the supporting units 40 remain in the region covered by the mask layer 200.

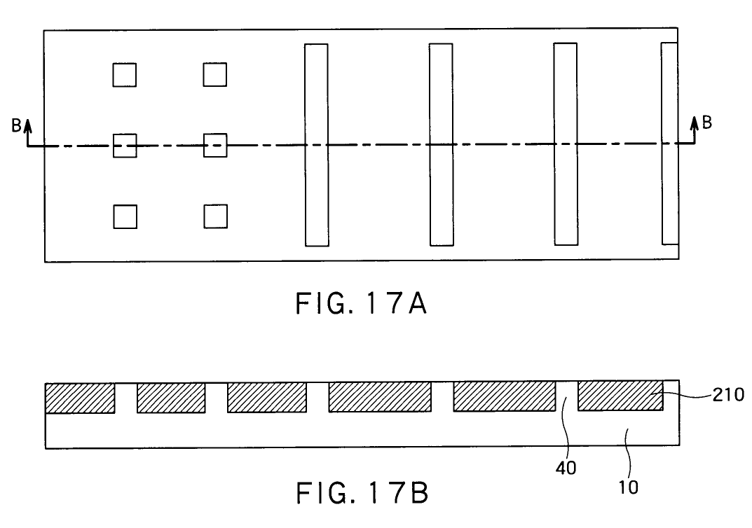

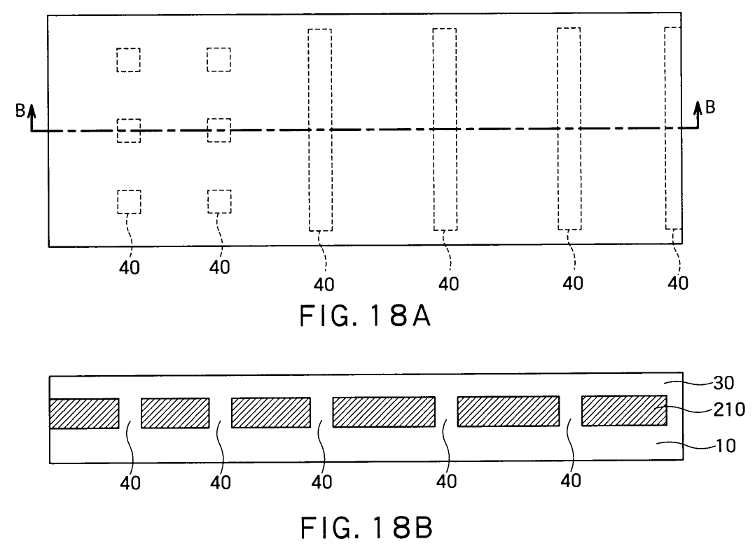

Next, as shown in FIG. 17A and FIG. 17B, the mask layer 200 is removed. Further, as shown in FIG. 18A and FIG. 18B, the silicon monocrystalline layer 30 is epitaxially grown on the porous silicon layer 210 and the supporting units 40.

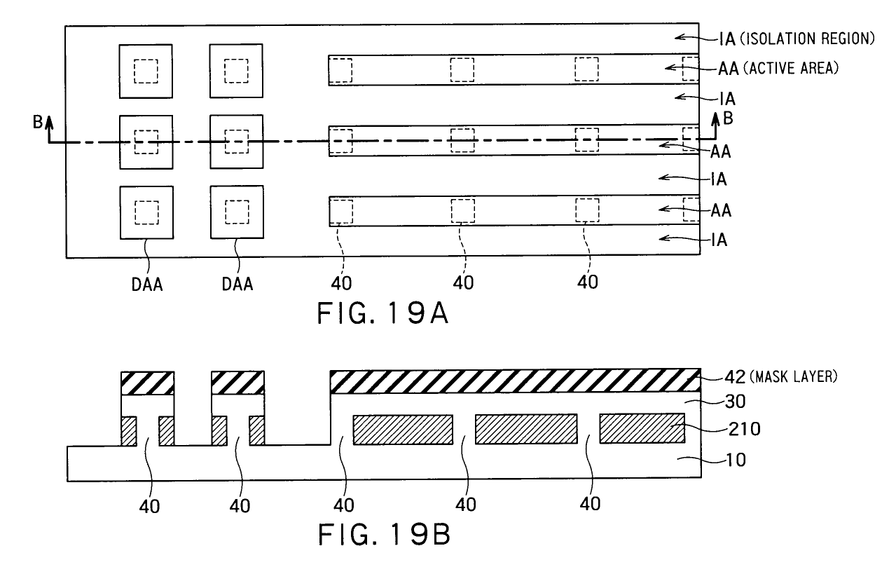

Next, the mask layer 42 is formed to cover the active areas AA and the dummy active areas DAA. The surface of the silicon layer 30 in the element isolation regions IA is exposed. The mask layer 42 includes a silicon nitride film, for example, and is processed using lithography and RIE. The silicon layer 30 and the porous silicon layer in the element isolation regions IA are anisotropically etched by using the mask layer 42 as a mask by RIE, as shown in FIG. 19A and FIG. 19B. Further, the porous silicon layer 210 beneath the silicon layer 30 is selectively and isotropically etched, while leaving the silicon layer 30 and the supporting units 40 in the dummy active areas DAA and the active areas AA as they are. Accordingly, a structure as shown in FIG. 6A and FIG. 6B is obtained. To etch the porous silicon layer 210, a hydrofluoric acid solution (for example, HF and H₂O₂ solution) can be used, for example. The porous silicon layer 210 is selectively etched in the bulk substrate 10 including silicon monocrystal and the supporting units 40, and the epitaxially grown silicon layer 30.

Thereafter, the process explained with reference to FIG. 6A to FIG. 7 is performed to complete the FBC memory shown in FIG. 1A and FIG. 1B.

A dummy gate (not shown) can be formed on or around the dummy active areas DAA by using a known CMOS process. The dummy gate is provided to avoid the occurrence of dishing in the flattening CMP process of the interlayer dielectric film 100.

In the second and the third embodiments, the porous silicon layer can be also manufactured by using anodization like in the fourth embodiment.

1. A semiconductor device comprising:
a bulk substrate;
an insulation layer provided on the bulk substrate;
a semiconductor layer containing an active area on which a semiconductor element is formed, and a dummy active area isolated from the active area and not formed with a semiconductor element thereon, the semiconductor layer being provided on the insulation layer; and
a supporting unit provided beneath the dummy active area to reach the bulk substrate piercing through the insulation layer, the supporting unit supporting the dummy active area.

2. The semiconductor device according to claim 1, wherein a periphery of the supporting unit is inside a periphery of the dummy active area when viewed from above the surface of the bulk substrate.

3. The semiconductor device according to claim 1, wherein the active area includes a floating body in the electrically floating state, and
a memory cell storing logical data based on the number of carriers within the floating body is formed in the active area.

4. The semiconductor device according to claim 1, further comprising a silicide layer provided on the dummy active area.

5. The semiconductor device according to claim 1, wherein the supporting unit is provided beneath the active area to reach the bulk substrate piercing through the insulation layer, and
the supporting unit supports the active area.

6. The semiconductor device according to claim 5, wherein the supporting unit is provided immediately beneath source or drain of a transistor provided in the active area.

7. The semiconductor device according to claim 5, wherein the supporting unit is provided immediately beneath the body of a transistor provided in the active area.

8. The semiconductor device according to claim 1, wherein the dummy active area is formed in a stripe shape or a ladder shape.

9. A method of manufacturing a semiconductor device, comprising:
forming a silicon germanium layer on a bulk substrate;
forming a first silicon monocrystalline layer on the silicon germanium layer;
removing a part of the first silicon monocrystalline layer and a part of the silicon germanium layer within a dummy active area isolated by an element isolation region from an active area in which a semiconductor element is to be formed;
forming a silicon pillar within a trench formed by removing the part of the first silicon monocrystalline layer and the part of the silicon germanium layer, and forming a second silicon monocrystalline layer on the first silicon monocrystalline layer;
removing the first and the second silicon monocrystalline layers and the silicon germanium layer in the element isolation region;
selectively removing the silicon germanium layer in the dummy active area, while leaving the first and the second silicon monocrystalline layers and the silicon pillar in the dummy active area; and
embedding an insulation layer beneath the first and the second silicon monocrystalline layers in the dummy active area.

10. The method of manufacturing a semiconductor device according to claim 9, wherein in removing the first silicon monocrystalline layer and the silicon germanium layer, a part of the first silicon monocrystalline layer and a part of the silicon germanium layer in the active area are removed.

11. A method of manufacturing a semiconductor device, comprising:
forming a mask layer on a bulk substrate;
removing a part of the mask layer within a dummy active area isolated by an element isolation region from an active area in which a semiconductor element is to be formed;
forming a porous silicon layer by selectively making porous the surface of the bulk substrate not covered by the mask layer, and forming a silicon pillar beneath the mask layer;
removing the mask layer;
forming a silicon monocrystal on the porous silicon layer and the silicon pillar;
removing the silicon monocrystalline layer and the porous silicon layer in the element isolation region;
selectively removing the porous silicon layer in the dummy active area, while leaving the silicon monocrystalline layer and the silicon pillar in the dummy active area; and
embedding an insulation layer beneath the silicon monocrystalline layer in the dummy active area.

12. The method of manufacturing a semiconductor device according to claim 11, wherein in removing the mask layer, a part of the mask layer within the active area is removed.
